(19) United States
(12) Patent Application Publication
(10) Pub. No.: US 2015/0069548 A1
(43) Pub. Date: Mar. 12, 2015

(54) MAGNETORESISTIVE ELEMENT

(71) Applicants: Masahiko NAKAYAMA, Seoul (KR); Tadashi KAI, Seoul (KR); Hiroaki YODA, Seoul (KR)

(72) Inventors: Masahiko NAKAYAMA, Seoul (KR); Tadashi KAI, Seoul (KR); Hiroaki YODA, Seoul (KR)

(21) Appl. No.: 14/200,394

(22) Filed: Mar. 7, 2014

Related U.S. Application Data
(60) Provisional application No. 61/875,442, filed on Sep. 9, 2013.

(51) Int. Cl. H01L 43/02

(52) U.S. Cl. CPC H01L 43/02
USPC 257/421

(57) ABSTRACT

According to one embodiment, a magnetoresistive element includes a storage layer having a variable magnetization direction, a reference layer having an invariable magnetization direction, a tunnel barrier layer formed between the storage layer and the reference layer, and a heater layer formed on an opposite side to the tunnel barrier layer of the storage layer. The storage layer includes a first layer formed on a side of the heater layer, and a second layer formed on the side of the tunnel barrier layer and having a Curie temperature higher than that of the first layer.

### CROSS-REFERENCE TO RELATED APPLICATIONS

This application claims the benefit of U.S. Provisional Application No. 61/875,442, filed Sep. 9, 2013, the entire contents of which are incorporated herein by reference.

### FIELD

Embodiments described herein relate generally to a magnetoresistive element.

### BACKGROUND

A spin transfer torque MRAM (Magnetic Random Access Memory) having a magnetoresistive element containing a ferromagnetic material as a memory element has been proposed. This MRAM is a memory that stores information by controlling the electrical resistance of the magnetoresistive element in two states of high resistance state/low resistance state by changing the magnetization direction in a magnetic layer by an electric current to be injected into the magnetoresistive element.

### BRIEF DESCRIPTION OF THE DRAWINGS

FIG. 1 is a circuit diagram showing a memory cell array of an MRAM according to an embodiment;

FIG. 2 is a plan view showing the memory cell array of the MRAM according to the embodiment;

FIG. 3 is a sectional view taken along a line A-A′ in FIG. 2;

FIG. 4A is a sectional view showing an outline configuration of a magnetoresistive element;

FIG. 4B is a view for explaining a write operation of the magnetoresistive element, and is a view showing a sectional view of the magnetoresistive element in a parallel state;

FIG. 4C is a view for explaining the write operation of the magnetoresistive element, and is a view showing a sectional view of the magnetoresistive element in an antiparallel state;

FIG. 5 is a sectional view showing a configuration of the magnetoresistive element according to the embodiment;

FIG. 6 is a view showing a sectional view and temperature of a storage layer at the time of performing a write operation in the embodiment;

FIG. 7 is a view showing a relationship between temperature and anisotropic energy of the storage layer in the embodiment;

FIG. 8 is a graph showing a relationship between an electric current flowing through a heater layer and an energy barrier ΔE of the storage layer in each of the embodiment and a comparative example;

FIG. 9 is a sectional view showing modification 1 of the configuration of the magnetoresistive element according to the embodiment; and

FIG. 10 is a sectional view showing modification 2 of the configuration of the magnetoresistive element according to the embodiment.

### DETAILED DESCRIPTION

In general, according to one embodiment, a magnetoresistive element comprises a storage layer having a variable magnetization direction; a reference layer having an invariable magnetization direction; a tunnel barrier layer formed between the storage layer and the reference layer; and a heater layer formed on an opposite side to the tunnel barrier layer of the storage layer. The storage layer includes a first layer formed on a side of the heater layer, and a second layer formed on the side of the tunnel barrier layer and having a Curie temperature higher than that of the first layer.

In an MRAM, a magnetoresistive element includes a storage layer that is a ferromagnetic layer in which a magnetization direction is a variable, a reference layer that is a ferromagnetic layer in which a magnetization direction is invariable, and a tunnel barrier layer that is a nonmagnetic layer formed between them. It is required to reduce reversal current (switching current) Ic in the storage layer to increase an energy barrier ΔE as the miniaturization of this magnetoresistive element advances. That is, it is desirable to reduce Ic/ΔE. Here the reversal current Ic is represented by expression (1) below by using the energy barrier ΔE, damping constant a, and polarization rate g:

Ic∝ΔE×a/g (1)

Those damping constant and polarization rate g have physical limits. Therefore, Ic/ΔE has a limitation in decreasing as the miniaturization of this magnetoresistive element advances. Accordingly, an assistant technique is necessary to reduce Ic/ΔE.

In the present embodiment, the energy barrier ΔE is temporarily reduced in the write operation by adding a thermal assistance. That is, the reversal current Ic can be reduced in the write operation.

The present embodiment will be explained below with reference to the accompanying drawings. In these drawings, the same reference numerals denote the same parts. Also, a repetitive explanation will be made as needed.

### Embodiment

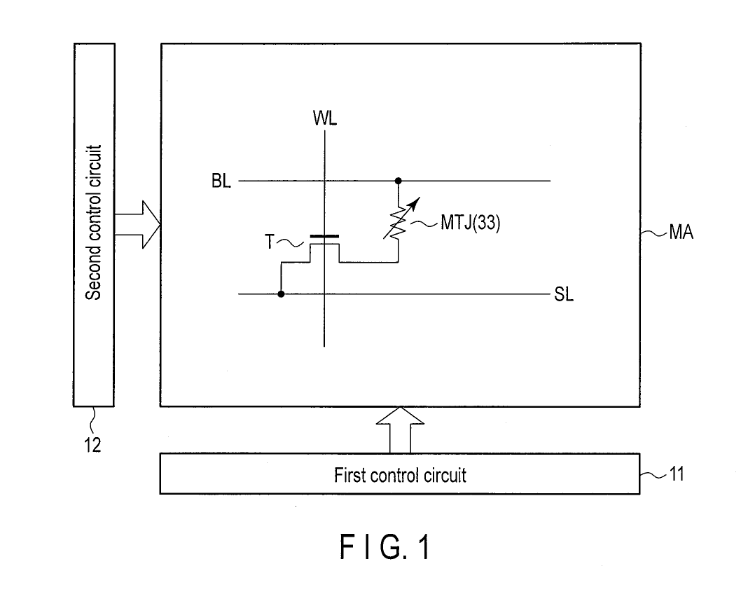

An MRAM according to the present embodiment will be explained below with reference to FIG. 1 to FIG. 10. In the MRAM according to the present embodiment, a storage layer 43 includes a first layer 43A having a low Curie temperature Tc, and a second layer 43B having a high Curie temperature Tc. And, by providing a heater layer 42 which contact the first layer 43A having the low Curie temperature Tc, the temperature of the first layer 43A is raised, resulting in reduction of the energy barrier ΔE of the first layer 43A. Thereby, the reversal current Ic of the storage layer 43 can be temporarily reduced in the write operation. The present embodiment will be explained in detail below.

### [MRAM Basic Configuration Example]

The basic configuration example of the MRAM according to the present embodiment will be explained with reference to FIGS. 1, 2, 3, 4A, 4B, and 4C.

FIG. 1 is a circuit diagram showing a memory cell array of the MRAM according to the present embodiment.

As shown in FIG. 1, a memory cell in the memory cell array MA includes a serial connection body of a magnetoresistive element 33 and a switching element (e.g., an FET) T. One end of the serial connection body (one end of the magnetoresistive element 33) is electrically connected to a bit line BL, and the other end of the serial connection body (one end of the switching element T) is electrically connected to a source line SL. The control terminal of the switching element T, for example, the gate electrode of the FET is electrically connected to a word line WL.

A first control circuit 11 controls electric potential of the word line WL. Besides, a second control circuit 12 controls the electric potentials of the bit line BL and the source line SL.

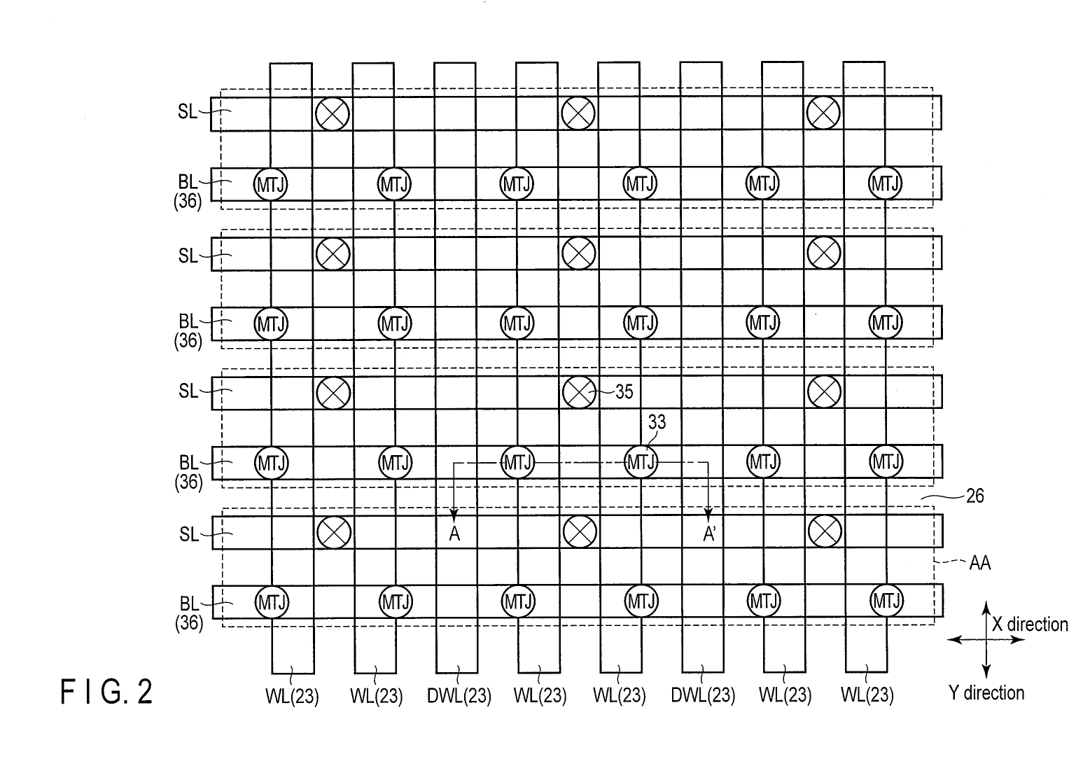

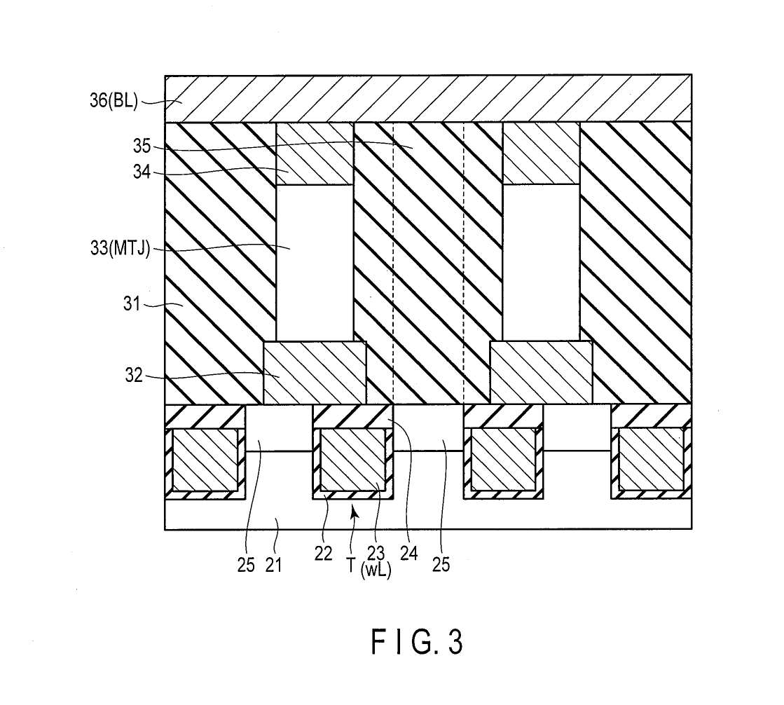

FIG. 2 is a plan view showing the memory cell array of the MRAM according to the present embodiment. FIG. 3 is a sectional view taken along a line A-A′ in FIG. 2. FIG. 3 shows a sectional view of a source line contact 35, in addition to a sectional view of the magnetoresistive element 33.

As shown in FIGS. 2 and 3, the memory cell array MA includes, for example, a plurality of word lines WL and a plurality of dummy word lines DWL extending in the Y direction, and a plurality bit lines BL and a plurality of source lines SL extending in the X direction perpendicular to the Y direction. Two word lines WL and one dummy word line DWL are alternately arranged along the X direction. Also, the bit line BL and source line SL are alternately arranged along the Y direction.

In the memory cell array MA, an element isolation insulating layer extending in the X direction is formed in the surface region of a p type semiconductor substrate (e.g., a silicon substrate) 21, and this region functions as an element isolation region 26. The surface region of the semiconductor substrate 21, in which the device isolation insulating layer is not provided becomes an active area AA. That is, the element isolation region 26 and active area AA are alternately formed along the Y direction. The element isolation insulating layer is formed of, for example, STI (Shallow Trench Isolation). As the element isolation insulating layer, an insulating material having a high filling characteristic such as silicon nitride (SiN) is used.

A selection transistor using, for example, an n channel MOSFET (Metal Oxide Semiconductor Field Effect Transistor) is formed as the switching element T in the semiconductor substrate 21. The select transistor has a structure in which a recess is formed in the semiconductor substrate 21 and the gate electrode 23 containing, for example, polycrystalline silicon is embedded in this recess.

More specifically, the selection transistor T includes a gate insulating layer 22, the gate electrode 23, and two diffusion layers 25 (a drain-side diffusion layer and source-side diffusion layer).

The gate insulating layer 22 is formed on an inner surface on the lower side of a recess extending in the Y direction formed on the surface of the semiconductor substrate 21. The gate electrode 23 is formed on the inner surface of the gate insulating layer 22 like filling in the lower side of the recess. This gate electrode 23 corresponds to the word line WL. An insulating layer 24 made of, for example, SiN is formed on top surfaces of the gate insulating layer 22 and the gate electrode 23 like filling in an upper side of the recess. The top surface of the insulating layer 24 is approximately as high as the top surface (top surface of the diffusion layers 25 described later) of the semiconductor substrate 21.

The two diffusion layers 25 are formed in the surface of the semiconductor substrate 21 like sandwiching the gate insulating layer 22, the gate electrode 23, and the insulating layer 24 therebetween. The diffusion layers 25 positioned between two neighboring memory cells along the X direction are shared by the two neighboring memory cells. On the other hand, although not shown, the diffusion layers 25 are isolated by the element isolation region 26 along the Y direction. In other words, the two diffusion layers 25 adjacent along the Y direction are adjacent via the element isolation region 26. That is, the diffusion layers 25 are positioned outside the formation region of the gate insulating layer 22, the gate electrode 23, and the insulating layer 24 in the active area AA. An interlayer dielectric layer 31 is formed on the semiconductor substrate 21 (on the insulating layer 24 and the diffusion layer 25).

A lower electrode 32, a magnetoresistive effect element 33, and an upper electrode 34 are formed in the interlayer dielectric layer 31 on one of the diffusion layers 25 (drain-side diffusion layer).

More specifically, the lower electrode 32 is formed so as to be in contact with a portion of the top surface of one of the diffusion layers 25 (drain-side diffusion layer) and a portion of the top surface of the insulating layer 24. In other words, the lower electrode 32 and the diffusion layer 25 partially overlap in a plane. This is because the processing method of the lower electrode 32 and that of the diffusion layer 25 (recess) are different. The plane shape of the interlayer dielectric layer 31 is, for example, square. The lower electrode 32 contains, e.g., TiN, but the material is not limited to this.

The magnetoresistive element 33 is formed in contact with the upper surface of the lower electrode 32. The magnetoresistive element 33 has, e.g., a circular planar shape, and is formed into a pillar shape. In other words, the magnetoresistive element 33 and lower electrode 32 overlap each other in a plane. Also, the planar area of the magnetoresistive element 33 is desirably smaller than that of the lower electrode 32. This makes it possible to bring the entire lower surface of the magnetoresistive element 33 into contact with the upper surface of the lower electrode 32, and reduce the contact resistance between them.

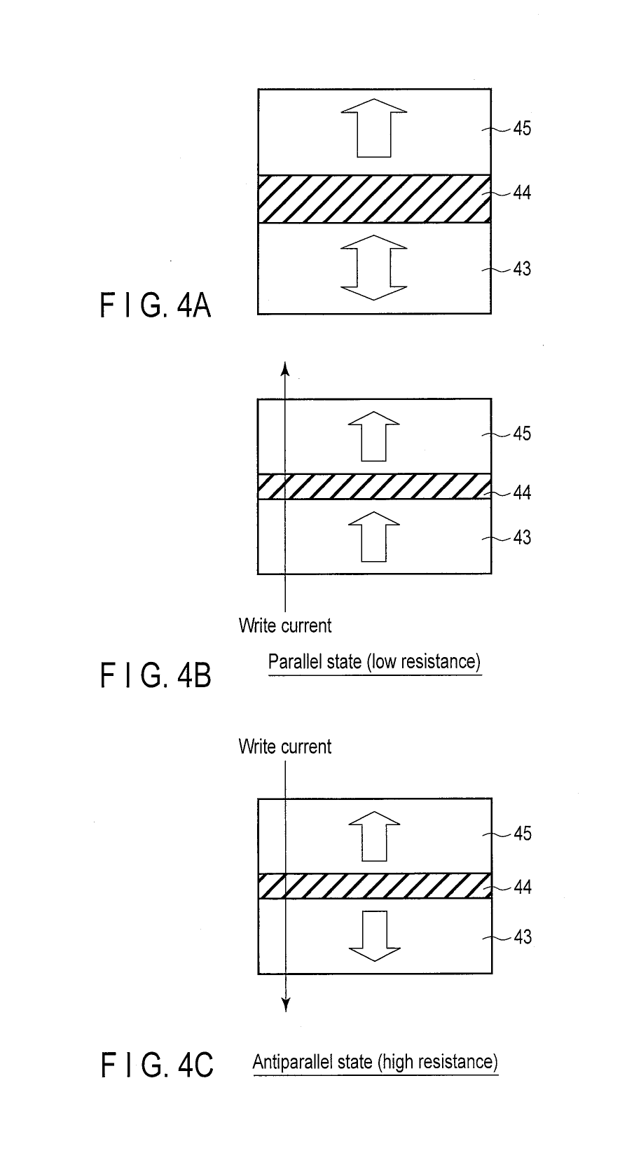

FIG. 4A is a sectional view showing an outline configuration of a magnetoresistive effect element. Here, the storage layer 43, the tunnel barrier layer 43, and the reference layer 45 are mainly shown as the magnetoresistive effect element 33.

As shown in FIG. 4A, the magnetoresistive effect element 33 contains a stacked body comprising the storage layer 43 that is a ferromagnetic (may simply be called magnetic) layer, the reference layer 44 that is a ferromagnetic layer, and the tunnel barrier layer 45 that is a non-magnetic layer formed therebetween.

The storage layer 43 is a ferromagnetic layer in which the magnetization direction is variable and has a perpendicular magnetic anisotropy that is perpendicular or approximately perpendicular to the film surface (top surface/bottom surface). Here, the magnetization direction is variable indicates that the magnetization direction changes for a predetermined write current. In addition, Being approximately perpendicular means that the direction of residual magnetization is in the range of 45°<θ≦90° with respect to the film surface.

The tunnel barrier layer 44 is formed on the storage layer 43. The tunnel barrier layer 44 is a nonmagnetic layer and is formed of, for example, MgO.

The reference layer 45 is formed on the tunnel barrier layer 44. The reference layer 45 is a ferromagnetic layer in which the magnetization direction is invariable, and has a perpendicular magnetic anisotropy that is perpendicular or approximately perpendicular to the film surface “The magnetization direction is invariable” herein mentioned means that the magnetization direction does not change with respect to a predetermined write current. That is, switching energy barrier of the magnetization direction of the reference layer 45 is larger than that of the storage layer 43.

FIG. 4B is a diagram illustrating a write operation of the magnetoresistive effect element and is a diagram showing a sectional view of the magnetoresistive effect element in a parallel state. FIG. 4C is a diagram illustrating the write operation of the magnetoresistive effect element and is a diagram showing a sectional view of the magnetoresistive effect element in an antiparallel state.

The magnetoresistive effect element 33 is, for example, a spin injection type magnetoresistive effect element. Thus, when data is written into the magnetoresistive effect element 33 or data is read from the magnetoresistive effect element 33, a current is passed to the magnetoresistive effect element 33 bidirectionally in a direction perpendicular to the film surface.

More specifically, data is written into the magnetoresistive effect element 33 as described below.

As shown In FIG. 4B, when a current flows from the lower electrode 32 to the upper electrode 34, that is, electrons (electrons from the reference layer 45 to the storage layer 43) are supplied from the side of the upper electrode 34, electrons spin-polarized in the same direction as the magnetization direction of the reference layer 45 are injected into the storage layer 43. In this case, the magnetization direction of the storage layer 43 is aligned with the same direction as the magnetization direction of the reference layer 45. Thereby, the magnetization direction of the reference layer 45 and the magnetization direction of the storage layer 43 are parallel arrays. In this parallel state, the value of resistance of the magnetoresistive effect element 33 is the smallest. This case is defined as, for example, data “0”.

On the other hand, when, as shown in FIG. 4C, a current flows from the upper electrode 34 to the lower electrode 32, that is, when electrons (electrons from the storage layer 43 to the reference layer 45) are supplied from the side of the lower electrode 32, electrons spin-polarized in a direction opposite to the magnetization direction of the reference layer 45 injected into the storage layer 43 due to being reflected by the reference layer 45. Thereby, the magnetization direction of the reference layer 45 and the magnetization direction of the storage layer 43 are antiparallel arrays. In this antiparallel state, the value of resistance of the magnetoresistive effect element 33 is the largest. This case is defined as, for example, data “1”.

In addition, data is read from the magnetoresistive effect element 33 as described below.

A read current is supplied to the magnetoresistive effect element 33. This read current is set to a value (value smaller than the write current) at which the magnetization direction of the storage layer 43 is not reversed. The data “0” or “1” can be read by detecting changes of the value of resistance of the magnetoresistive effect element 33 at this point.

As shown in FIG. 3, the upper electrode 34 is formed so as to be in contact with the top surface of the magnetoresistive effect element 33. The bit line BL is formed on the upper electrode 34 so as to be in contact therewith. That is, the upper electrode 34 is a bit line contact.

Also, the source line contact 35 is formed in the interlayer dielectric layer 31 on the other diffusion layer 25 (the source-side diffusion layer). The source line contact 35 is formed so as to be in contact with the top surface of the other diffusion layer 25. The source line SL is formed on this source line contact 35 so as to be in contact therewith. The other diffusion layer 25 and the source line contact 35 are shared by two neighboring memory cells.

Among the three gate electrodes 23 adjacent in the X direction, the two gate electrodes 23 are electrically connected to the magnetoresistive effect element 33 and correspond to the word like WL, and the one gate electrode 23 is not electrically connected to the magnetoresistive effect element 33 and corresponds to the dummy word line DWL.

### [Configuration of the Magnetoresistive Effect Element According to the Embodiment]

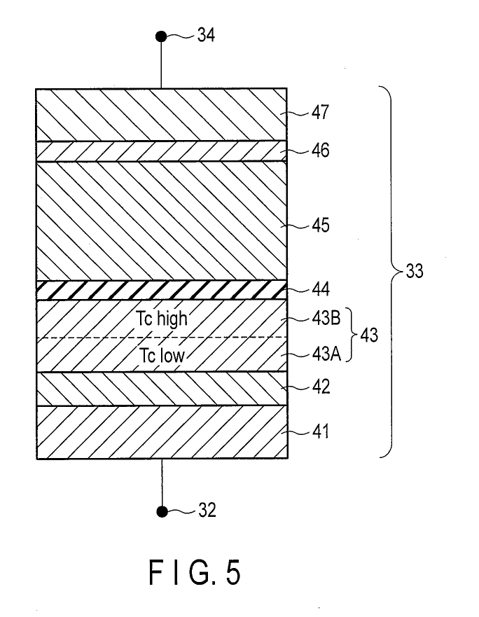

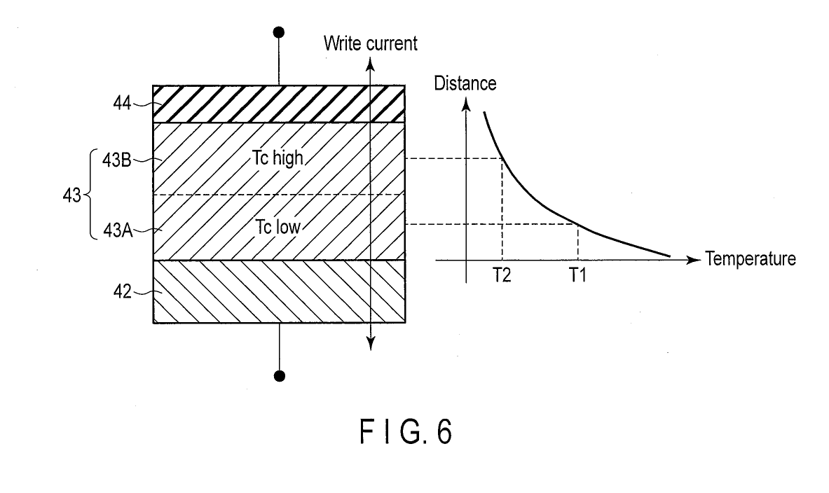

The configuration of the magnetoresistive element 33 according to the present embodiment will be explained with reference to FIGS. 5 and 6.

FIG. 5 is a sectional view showing the configuration of the magnetoresistive element according to the present embodiment.

As shown in FIG. 5, the magnetoresistive element 33 according to the present embodiment is electrically connected to the lower electrode 32 and upper electrode 34, and comprises an underlying layer 41, the heater layer 42, the storage layer 43, the tunnel barrier layer 44, the reference layer 45, an interlayer 46, and a shift cancelling layer 47.

The underlying layer 41 is formed on the lower electrode 32. The underlying layer 41 contains a nonmagnetic material having conductivity. Examples of such a nonmagnetic material are W, Mo, Ta, Hf, Nb, Al, Ti, and oxides or nitrides thereof. It is also possible to use an alloy or multilayered film of these elements.

The heater layer 42 is formed on the underlying layer 41. The heater layer 42 is, for example, a heating resistor. In addition, the heater layer 42 is electrically connected to the lower electrode 32 and upper electrode 34 via the each layers of the magnetoresistive element 33. Therefore, the heater layer 42 generates heat by causing a current (write current) to flow an electricity path between the lower electrode 32 and upper electrode 34. And the temperature of the first layer 43A can be raised as the heater layer 42 contacts a first layer 43A of the storage layer 43 to be described below.

The storage layer 43 is formed on the underlying layer 41. The storage layer 43 contains ferromagnetic materials such as Co and Fe. In addition, B is added to the ferromagnetic material for the purpose of adjusting saturation magnetization or crystal magnetic anisotropy. That is, the storage layer 43 comprises a compound, for example, CoFeB or the like. Details of the storage layer 43 in the present embodiment will be described later.

The tunnel barrier layer 44 is formed on the storage layer 42. The tunnel barrier layer 44 contains a nonmagnetic material, for example, MgO or the like. However, the present embodiment is not limited to such an example and the tunnel barrier layer 44 may contain metallic oxide such as Al₂O₃, MgAlO, ZnO, or TiO.

The reference layer 45 is formed on the tunnel barrier layer 44. The reference layer 45 comprises, for example, a stacked structure of a first magnetic layer, a nonmagnetic layer, and a second magnetic layer formed from the side of the tunnel barrier layer.

The first magnetic layer contains a ferromagnetic material like, for example, Co and Fe. B is added to the ferromagnetic material for the purpose of adjusting saturation magnetization or crystal magnetic anisotropy. That is, the first magnetic layer is formed of, for example, a compound such as CoFeB same as the storage layer 43. The first magnetic layer is a layer contributing to the MR ratio. The nonmagnetic layer is formed between the first magnetic layer and the second magnetic layer. The nonmagnetic layer contains a nonmagnetic material like Ta, W, or Hf. The second magnetic layer contains a ferromagnetic material and a nonmagnetic material. For example, Pt can be cited as the nonmagnetic material. As the ferromagnetic material, for example, Co is contained as a ferromagnetic material. That is, the second magnetic layer comprises a stacked film, for example, a Pt layer and a Co layer. This stacked film comprises a plurality of Pt layers and a plurality of Co layers being alternately stacked. The second magnetic layer contributes to perpendicular magnetic anisotropy.

The shift cancelling layer 47 is formed on the reference layer 45 via the interlayer 46. The interlayer 46 contains a conductive nonmagnetic material such as Ru. The shift cancelling layer 47 is a magnetic layer having an invariable magnetization direction, and has perpendicular magnetic anisotropy perpendicular or almost perpendicular to the film surfaces. In addition, the magnetization direction is opposite to the magnetization direction of the reference layer 45. Thereby, the shift cancelling layer 47 can cancel a leakage magnetic field applied from the reference layer 45 to the storage layer 43. In other words, the shift cancelling layer 47 has an effect of adjusting, an offset of reversal characteristics for the storage layer 43 due to the leakage magnetic field from the reference layer 45, to the opposite direction. The shift cancelling layer 47 comprises, for example, an artificial lattice including a multilayered structure of a ferromagnetic material such as Ni, Fe, or Co and a nonmagnetic material such as Cu, Pd, or Pt. The upper electrode 34 is formed on the shift cancelling layer 47.

The storage layer 43 in the present embodiment comprises the first layer 43A and second layer 43B.

The first layer 43A is formed on the heater layer 42. In addition, the first layer 43A is formed in a manner that the lower surface thereof contacts the heater layer 42. The second layer 43B is formed on the first layer 43A. In addition, the second layer 43B is formed in a manner that the upper surface thereof contacts the tunnel barrier layer 44. In other words, in the storage layer 43, the first layer 43A is formed on the side of the heater layer 42, and the second layer 43B is formed on the side of the tunnel barrier layer 44.

The first layer 43A has a low Curie temperature Tc, and the second layer 43B has a high Curie temperature Tc. That is, the Curie temperature Tc of the first layer 43A is lower than the Curie temperature of the second layer 43B. The Curie temperature Tc of Co is normally higher than the Curie temperature of Fe. Therefore, when the first layer 43A and second layer 43B comprise CoFeB, the Fe concentration of CoFeB in the first layer 43A is set higher than the Fe concentration of CoFeB in the second layer 43B so as to make the Curie temperature Tc of the first layer 43A lower than the Curie temperature of the second layer 43B.

It is note that the material of the first layer 43A and second layer 43B is not limited to CoFeB. To make the Curie temperature Tc of the first layer 43A lower than the Curie temperature of the second layer 43B, the first layer 43A may comprises an alloy containing a rare earth element and Fe or Co, or an alloy containing a noble metal element (e.g., Pt or Pd) and Fe or Co. On the other hand, the second layer 43B may comprise an alloy containing Fe or Co.

FIG. 6 is a view showing a sectional view and temperature of a storage layer at the time of performing a write operation in the present embodiment.

As shown in FIG. 6, in the write operation, a write current flows through the magnetoresistive element 33 from the lower electrode 32 to the upper electrode 34 or from the upper electrode 34 to the lower electrode 32. This write current causes the heater layer 42 to generate heat. And the heat generated by the heater layer 42 raises the temperature of the storage layer 43. At this time, as shown by the diagram, the rise in temperature increases as the distance from the heater layer 42 is shorter, and decreases as the distance from the heater layer 42 is longer. That is, the temperature of a middle portion (interlayer) of the second layer 43B, which is far from the heater layer 42 is T2, and the temperature of a middle portion (interlayer) of the first layer 43A, which is close to the heater layer 42 is T1 higher than T2.

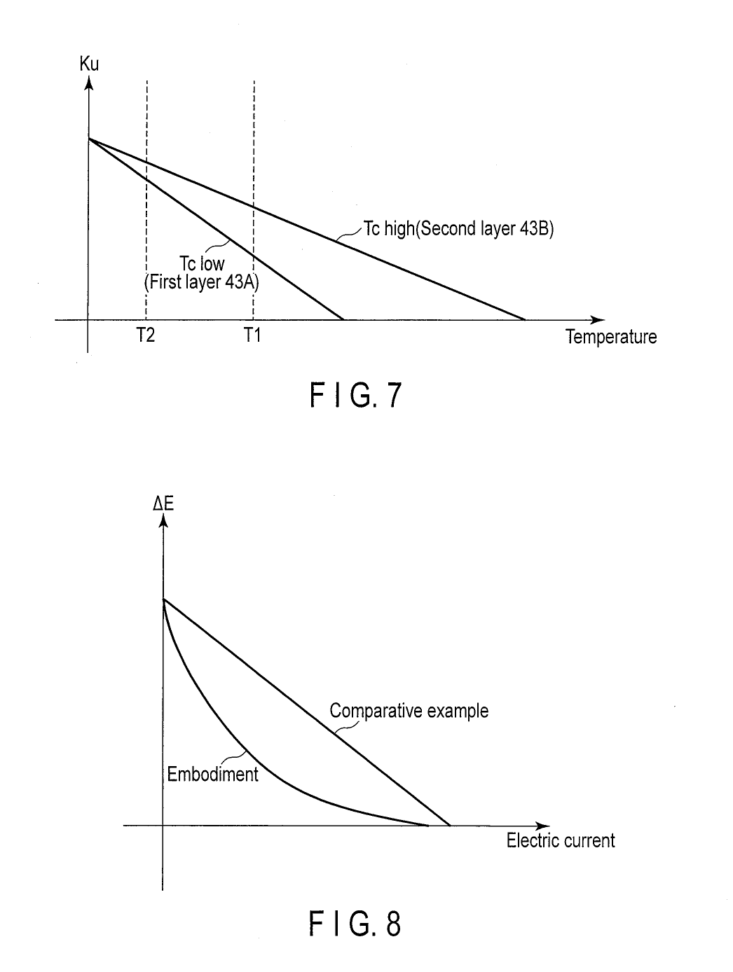

FIG. 7 is a view showing a relationship between temperature and anisotropic energy of the storage layer in the present embodiment.

As shown in FIG. 7, when the temperature of the storage layer 43 rises, an anisotropic energy Ku reduces. Here, the anisotropic energy Ku and energy barrier ΔE have a relationship indicated by:

ΔE=KuV/kBT (2)

Where V is a volume, kB is the Boltzmann constant, and T is room temperature. That is, when the temperature of the storage layer 43 rises, the energy barrier ΔE thereof reduces.

In addition, as shown by the diagram, the reduction rate of the anisotropic energy Ku (the energy barrier ΔE) resulting from the temperature rise is higher in the first layer 43A having the low Curie temperature Tc than in the second layer 43B having the high Curie temperature Tc. This is because that the first layer 43A having the low Curie temperature Tc loses magnetism at lower temperature than the second layer 43B having the high Curie temperature Tc.

In the present embodiment, the first layer 43A having the low Curie temperature Tc is formed close to the heater layer 42. Then, in the write operation, the temperature is raised to the high temperature T1. Thereby, the magnetism (e.g., the anisotropic energy Ku) of the storage layer 43 can be reduced more efficiently than when the second layer 43B having the high Curie temperature Tc is formed close to the heater layer 42 (when the temperature of the second layer 43B is raised to the high temperature T1). That is, the energy barrier ΔE (the switching current Ic) of the storage layer 43 can efficiently be reduced in the write operation.

Furthermore, the planar shape of the underlying layer 41, heater layer 42, storage layer 43, tunnel barrier layer 44, reference layer 45, interlayer 46, and shift cancelling layer 47 is, for example, a circle. Therefore, the magnetoresistive element 33 is formed into a pillar shape. However, the planar shape of the magnetoresistive element 33 is not limited to this, and may be a square, rectangle, ellipse, or the like.

Furthermore, the storage layer 43 and reference layer 45 may have a dimensional difference in a plane. For example, the diameter of the reference layer 45 may be smaller than the diameter of the storage layer 43 in a plane. And as a sidewall of the reference layer 45, an insulating layer of a dimensional difference to the storage layer 43 may be formed. Thereby, an electrical short circuit between the storage layer 43 and reference layer 45 can be prevented.

Furthermore, the order of arrangement may be reversed in the configuration of the magnetoresistive effect element 33. That is, the shift cancelling layer 47, interlayer 46, reference layer 45, tunnel barrier layer 44, second layer 43B, first layer 43A, heater layer 42, and underlying layer 41 may be formed in this order on the lower electrode 32.

### [Method of Manufacturing Magnetoresistive Element According to Embodiment]

A method of manufacturing the magnetoresistive element 33 according to the present embodiment will be explained.

First, the interlayer dielectric layer 31 of a lower electrode 32 formation region is formed on the semiconductor substrate 21 by, for example, CVD (Chemical Vapor Deposition) method. Next, a hole not shown reaching the semiconductor substrate 21 is formed in the interlayer dielectric layer 31 by, for example, lithography technology. Thereafter, the lower electrode 32 is formed in this hole by, for example, CVD method. The lower electrode 32 contains, for example, TiN, but it is not limited to this.

Next, the underlying layer 41 is formed on the lower electrode 32, for example, sputtering method. The underlying layer 41 contains a conductive nonmagnetic material. Examples of such a nonmagnetic material are W, Mo, Ta, Hf, Nb, Al, Ti, and oxides or nitrides thereof. Alternatively, it may be an alloy or multilayered film of these elements.

Next, the heater layer 42 is formed on the underlying layer 41. The heater layer 42 is, for example, a heating resistor.

Next, the storage layer 43 is formed on the heater layer 42 by, for example, sputtering method. The storage layer 43 comprises a compound such as CoFeB. The storage layer 43 is formed by forming the first layer 43A on the heater layer 42, followed by forming the second layer 43B on the first layer 43A. The Curie temperature Tc of the first layer 43A is lower than Curie temperature Tc of the second layer 43B. For this reason, for instance, the Fe concentration of CoFeB in the first layer 43A is set higher than the Fe concentration of CoFeB in the second layer 43B. The first layer 43A and second layer 43B as described above can be formed by changing targets in sputtering method, and can also be formed by changing the wattage of each target.

Next, the tunnel barrier layer 44 is formed on the storage layer 43. The tunnel barrier layer 44 contains a nonmagnetic material such as MgO. The MgO layer constituting the tunnel barrier layer 44 may be formed by directly forming an MgO layer by sputtering method using an MgO target, or may be formed by forming an Mg layer by sputtering method using an Mg target, and then oxidizing the Mg layer. To increase the MR ratio, it is desirable to directly form the MgO layer by sputtering method using the MgO target.

Next, the reference layer 45 is formed on the tunnel barrier layer 44 by, for example, sputtering method. The reference layer 45 comprises a multilayered structure of a first magnetic layer, nonmagnetic layer, and second magnetic layer formed in this order from the side of the tunnel barrier layer 44.

Like the storage layer 43, the first magnetic layer comprises a compound such as CoFeB. The first magnetic layer is a layer that contributes to the MR ratio. The nonmagnetic layer is formed between the first magnetic layer and second magnetic layer. The nonmagnetic layer contains a nonmagnetic material such as Ta, W, or Hf. The second magnetic layer contains a ferromagnetic material and nonmagnetic material. An example of the nonmagnetic material is Pt. Furthermore, an example of the ferromagnetic material contains Co. That is, the second magnetic layer comprises, for example, a multilayered film of a Pt layer and a Co layer. This multilayered film is configured by alternately stacking a plurality of Pt layers and a plurality of Co layers. The second magnetic layer contributes to the perpendicular magnetic anisotropy. The second magnetic layer like this is formed by changing targets in sputtering method.

Next, the interlayer 46 including Ru is formed on the reference layer 45 by, for example, sputtering method, and a shift cancelling layer 47 is formed on the interlayer 46 by, for example, sputtering method. The shift cancelling layer 47 is formed by, for example, an artificial lattice including a multilayered structure of a ferromagnetic material such as Ni, Fe, Co and a nonmagnetic material such as Cu, Pd, Pt.

Thereafter, the each layers of the magnetoresistive element 33 are crystallized by performing annealing.

Next, a hard mask not shown is formed on the shift cancelling layer 47, and patterned such that its planar shape becomes a circle. The hard mask comprises a conductive metal material, for example, TiN. However, it is not limited to this, and the hard mask may be configured by a film containing Ti, Ta, or W, or a multilayered film of these elements. Thereby, the hard mask need not be removed later, and can be used as a contact portion for an upper electrode 34.

Next, the shift cancelling layer 47, interlayer 46, reference layer 45, tunnel barrier layer 44, storage layer 43, heater layer 42, and underlying layer 41 are processed by physical etching such as ion milling busing the hard mask as a mask. Thereby, the shift cancelling layer 47, the interlayer 46, the reference layer 45, the tunnel barrier layer 44, the storage layer 43, the heater layer 42, and the underlying layer 41 are patterned to have a circular planar shape, like the hard mask.

Next, the interlayer dielectric layer 31 of the magnetoresistive element 33 formation region is formed by, for example, CVD method. Thereby, the interlayer dielectric layer 31 is buried between adjacent magnetoresistive elements 33. Thereafter, the interlayer dielectric layer 31 formed on the magnetoresistive element 33 is planarized, followed by etched back. Thereby, the upper surface of the magnetoresistive element 33 is exposed.

Next, the interlayer dielectric layer 31 of the upper electrode 34 formation region is formed to the magnetoresistive element 33. Next, a hole not shown reaching the magnetoresistive element 33 is formed in the interlayer dielectric layer 31 by, for example, lithography technology. Thereafter, an upper electrode 34 is formed in this hole by, for example, CVD method, and electrically connected to the magnetoresistive element 33.

In this manner, the magnetoresistive element 33 according to the present embodiment is formed.

### Effects of Embodiment

FIG. 8 is a graph showing a relationship between an electric current flowing through the heater layer and the energy barrier ΔE of the storage layer in each of the present embodiment and a comparative example.

In the above-mentioned embodiment, the storage layer 43 includes the first layer 43A having the low Curie temperature Tc, and the first layer 43A is formed close to the heater layer 42. That is, the first layer 43A is formed closer to the heater layer 42 than the second layer 43B. And by following the write current in the write operation, causing heat in the heater layer 42, and the temperature of the first layer 43A is raised to the high temperature T1. Thereby, the magnetism (e.g., the anisotropic energy Ku) of the storage layer 43 can efficiently be reduced. That is, as shown in FIG. 8, the present embodiment can efficiently reduce the energy barrier ΔE of the storage layer 43 in the write operation than the comparative example in which the storage layer is configured by only the layer having the high Curie temperature Tc. Accordingly, the reversal current Ic can temporarily be reduced in the write operation.

However, when the entire storage layer 43 is configured by a layer having the low Curie temperature Tc, the magnetic characteristic (e.g., the MR ratio) of the storage layer is deteriorated by the composition ratio thereof or the like. By contrast, the storage layer 43 of the present embodiment includes the second layer 43B having the high Curie temperature Tc. Thereby, the deterioration of the magnetic characteristic of the storage layer 43, which is caused by the formation of the first layer 43A, can be suppressed.

### Modifications

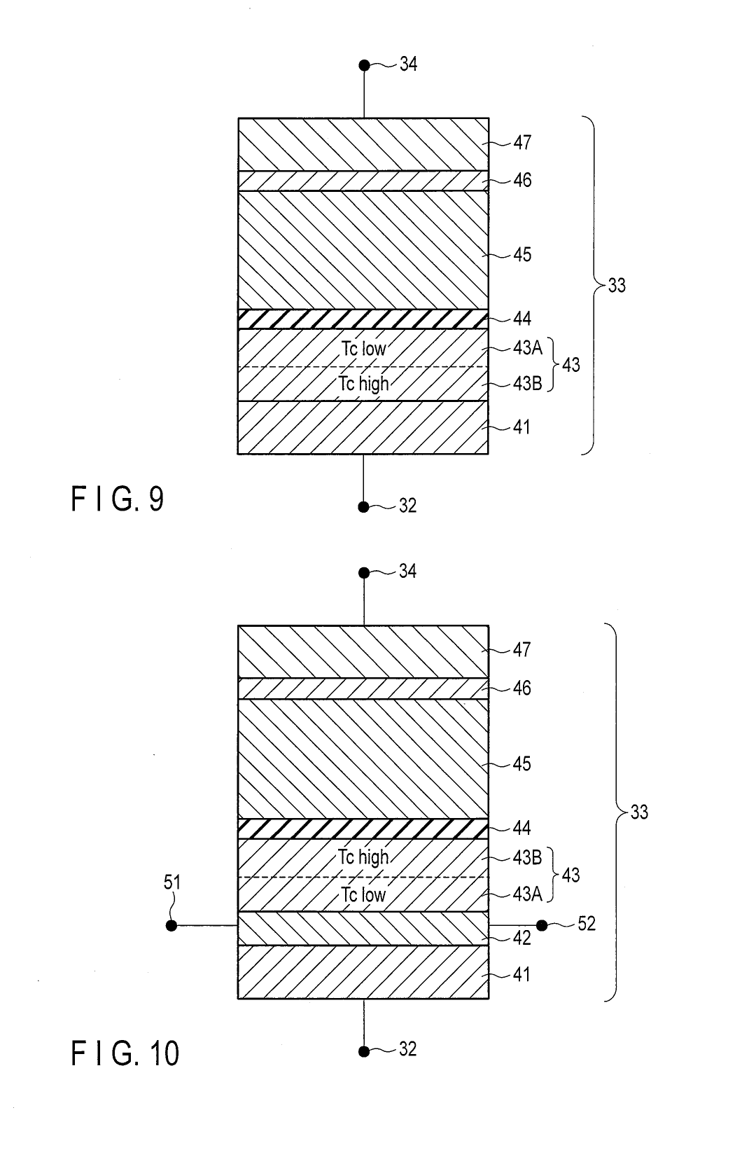

Modifications of the magnetoresistive element 33 according to the present embodiment will be explained with reference to FIG. 9 and FIG. 10.

FIG. 9 is a sectional view showing modification 1 of the configuration of the magnetoresistive element according to the present embodiment. FIG. 10 is a sectional view showing modification 2 of the configuration of the magnetoresistive element according to the present embodiment.

As shown in FIG. 9, in modification 1, the first layer 43B having the low Curie temperature Tc is formed in contact with the tunnel barrier layer 44, and the tunnel barrier layer 44 comprises a function as a heater layer.

More specifically, the second layer 43B having the high Curie temperature Tc is formed on the underlying layer 41. Furthermore, the second layer 43B is formed in a manner that the lower surface thereof contacts the underlying layer 41. Furthermore, the first layer 43A having the low Curie temperature Tc is formed on the second layer 43B. Furthermore, the first layer 43A is formed in a manner that the upper surface thereof contacts the tunnel barrier layer 44. In other words, in the storage layer 43, the first layer 43A is formed on the side of the tunnel barrier layer 44, and the second layer 43B is formed on the side of the underlying layer 42.

The tunnel barrier layer 44 comprises a resistor having a resistance higher than the resistance of the underlying layer 41 comprising the conductor. In addition, the tunnel barrier layer 44 is electrically connected to the lower electrode 32 and upper electrode 34 via the each layers of the magnetoresistive element 33. For this reason, by causing an electric current to flow an electricity path between the lower electrode 32 and upper electrode 34, the tunnel barrier layer 44 generates more heat than the underlying layer 41. That is, the tunnel barrier layer 44 functions as a heat resistor. And as the tunnel barrier layer 44 contacts the first layer 43A of the storage layer 43, the temperature of the first layer 43A can be raised higher than the second layer 43B which contacts the underlying layer 41. Thereby, the same effects as those of the above-mentioned embodiment can be obtained in modification 1.

As shown in FIG. 10, in modification 2, the heater layer 42 is electrically connected to an independent electricity path.

More specifically, the heater layer 42 is directly electrically connected to a first electrode 51 and a second electrode 52. For this reason, by causing an electric current to flow the electricity path between the lower electrode 32 and the upper electrode 34, and by causing an electric current to flow an electricity path between the first electrode 51 and the second electrode 52 independent of the lower electrode 32 and upper electrode 34, the heater layer 42 generates heat. And as the heater layer 42 contacts the first layer 43A of the storage layer 43, the temperature of the first layer 43A can be raised.

Thereby, in modification 2, by causing a heating current to flow between the first electrode 51 and the second electrode 52 independently of the write current following between the lower electrode 32 and upper electrode 34, the heat of the heater layer 42 can generated. Therefore, the temperature control of the storage layer 43 can be performed more easily.

It is note that modification 2 may be applicable to modification 1. That is, the tunnel barrier layer 44 is directly electrically connected to the first electrode 51 and the second electrode 52. For this reason, by causing the electric current to flow the electricity path between the lower electrode 32 and the upper electrode 34, and by causing the electric current to flow the electricity path between the first electrode 51 and the second electrode 52 independent of the lower electrode 32 and upper electrode 34, the tunnel barrier layer 44 generates heat.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetoresistive element comprising:
a storage layer having a variable magnetization direction;
a reference layer having an invariable magnetization direction;
a tunnel barrier layer formed between the storage layer and the reference layer; and
a heater layer formed on an opposite side to the tunnel barrier layer of the storage layer,
wherein the storage layer includes a first layer formed on a side of the heater layer, and a second layer formed on the side of the tunnel barrier layer and having a Curie temperature higher than that of the first layer.

2. The element of claim 1, wherein the first layer and the second layer contain Fe, and Fe concentration in the first layer is higher than Fe concentration in the second layer.

3. The element of claim 1, wherein the first layer comprises alloy containing a rare earth element and Fe or Co, or an alloy containing a noble metal element and Fe or Co, and the second layer comprises an alloy containing Fe or Co.

4. The element of claim 1, further comprising an upper electrode and a lower electrode which are electrode electrically connected to the storage layer, the reference layer.

5. The element of claim 1, further comprising a first electrode and a second electrode which are electrically connected to the heater layer.

6. The element of claim 1, wherein the heater layer is a heating resistor.

7. The element of claim 1, wherein the first layer and the second layer contain Co and Fe.

8. A magnetoresistive element comprising:
a storage layer in which a magnetization direction is variable;
a reference layer in which a magnetization direction is invariable; and
a tunnel barrier layer formed between the storage layer and the reference layer,
wherein the storage layer includes a first layer formed on a side of the tunnel barrier layer, and a second layer formed on an opposite side to the tunnel barrier layer and having a Curie temperature higher than that of the first layer.

9. The element of claim 8, wherein the first layer and the second layer contain Fe, and Fe concentration in the first layer is higher than that in the second layer.

10. The element of claim 8, wherein the first layer comprises an alloy containing a rare earth element and Fe or Co, or an alloy containing a noble metal element and Fe or Co, and the second layer comprises an alloy containing Fe or Co.

11. The element of claim 8, further comprising an upper electrode and a lower electrode which are electrically connected to the storage layer, the reference layer.

12. The element of claim 8, further comprising a first electrode and a second electrode which are electrically connected to the tunnel barrier layer.

13. The element of claim 8, wherein the tunnel barrier layer is a heating resistor.

14. The element of claim 8, wherein the first layer and the second layer contain Co and Fe.
